(19) United States
(12) Patent Application Publication
(10) Pub. No.: US 2022/0158676 A1
(43) Pub. Date: May 19, 2022

(54) RF DOWNCONVERTER-TUNER

(71) Applicant: ThinkRF Corporation, Kanata (CA)

(72) Inventors: Nikhil Adnani, Kanata (CA); Gilbert Brunette, Ottawa (CA)

(21) Appl. No.: 16/952,462

(22) Filed: Nov. 19, 2020

(51) Int. Cl. H04B 1/28; H04B 1/00; H04B 1/403; H03D 7/16

(52) U.S. Cl. CPC H04B 1/28; H03D 7/161; H04B 1/406; H04B 1/005

(57) ABSTRACT

A RF downconverter-tuner system is provided. A RF downconverter-tuner system to convert one or more input signals into a lower range of frequency bands, comprising one or more RF input ports for receiving the one or more input signals, one or more RF output ports for transmitting the output signal and a plurality of dual-mode switches coupled to two or more of the one or more RF input ports, the one or more RF output ports and one or more receive chain comprising one or more mixers for converting the one or more input signals into the lower range of frequency bands, a plurality of filters, a bypass mode, a back-end receiver coupled to the one or more RF output ports, an oscillator implemented with a frequency synthesis circuit, a plurality of amplifier stages, one or more signal detection circuits and a plurality of controller ports.

### FIELD OF THE INVENTION

The present disclosure relates to an RF downconverter-tuner, more specifically but not by way of limitation, a downconverter-tuner that transforms an input frequency into a lower output frequency.

### BACKGROUND

Increased demands for increased wireless services and higher data rates are driving the development and deployment of mmWave 5G networks. Wireless networks from 2G to 5G, in addition to a multitude of other wireless systems, is making RF spectrum monitoring more challenging and complex. With increasing diversity and complexity in the wireless signals being transmitted, RF engineers require robust and versatile solutions to monitor and analyze the RF signals in their fields of operation.

Currently, most devices operate below 6 GHz, including the majority of the test and measurement equipment which support these devices. An RF downconverter is employed to transform high frequency analog signals to a lower frequency range where they can be processed by other equipment. Current RF test and measurement solutions cannot accommodate this new RF signal environment and for many RF operators, replacing their existing equipment with higher frequency equipment is not a practical option. RF professionals are seeking more innovative and cost-effective ways to meet the challenges of this new RF world. Rather than buying increasingly complex and more costly equipment, RF professionals now have other options. Downconverter-tuners can be an integral part of an RF signal measurement solution for higher frequency applications. Deployed in conjunction with other RF measurement components, these devices can extend the frequency range of existing test and measurement equipment, enabling high performance at a much lower cost than other all-in-one-box solutions. For instance, a downconverter-tuner may be used in conjunction with a spectrum analyzer. This analyzer could be a benchtop, handheld, software-defined radio or PXI instrumentation. The downconverter-tuner simply converts high frequency signal at the RF input to a lower frequency signal at its IF output. The latter is input to a spectrum analyzer and can be processed by it.

Apart from the contention for limited spectrum in an increasingly wireless world, the types of wireless signals that are being studied and deployed are becoming more diverse and sophisticated. Combined with other technologies that use intermittent, pulsed, frequency-hopping signals and signals masked by noise that vary dynamically in amplitude, it is easy to see how identifying and measuring these signals reliably has become more difficult.

RF professionals in A&D industries are seeing this challenge first-hand: modern radar and Electronic Warfare (EW) signals in A&D environments are dynamic in nature, and inherently difficult to measure. EW signals are moving to higher frequencies to avoid conflicts with other mobile operators, and frequency-hopping signals are increasingly difficult to measure with older spectrum monitoring systems that do not support wider bandwidths for signal capture and analysis.

As new threats continue to emerge, military agencies must be able to adapt their test and monitoring systems to meet new operational requirements in an agile manner, while managing ever-tighter resources and budgets.

The increasing complexity in the RF environment requires a corresponding evolution in the test and measurement equipment that RF engineers use to monitor it. According to their “RF Test Equipment Market Research Report—Forecast to 2023” report, Market Research Future estimates the global RF test equipment market to reach USD 3.21 billion by 2023 (up from USD 2.41 billion in 2017)^{[1]}, driven in large part by the growth in wireless demand and IoT connectivity.

Large industry players continue to develop more powerful and more sophisticated monitoring equipment with feature-rich functionality—and a price tag to match. This “Swiss army knife” approach, however, is not necessarily efficient and is rarely cost-effective, particularly for in-the-field deployment scenarios that require multiple analyzers to be deployed for accurate signal monitoring.

This poses a dilemma for RF engineers who need to keep pace with emerging technologies: what to do with the signal monitoring equipment they already have.

The leaps in technology and computing in RF test and measurement devices in recent years has highlighted a challenge for the organizations using them—namely, the obsolescence of their existing equipment.

For example, while adoption of 5G technologies will undoubtedly create significant growth opportunities for the communications sector, operating in that space requires RF test equipment that is compatible with 5G technology. Most RF measurement equipment currently deployed in the field does not support those higher frequencies, and organizations that want to take advantage of 5G applications must seek alternatives in either testing equipment or testing strategies.

Likewise, RF professionals who are dealing with more complex signals wideband frequency hopping, for example—require signal capture equipment that supports wider bandwidths than previously required.

A&D organizations have often fallen prey to this dilemma, as many of their RF systems and applications (and the measurement systems used to test and monitor them) have been custom-built for a single purpose. As such, they are rarely adaptable beyond their original design, and cannot be upgraded easily.

With the galloping pace of innovation in RF applications and technology, RF engineers are looking for ways to future-proof their existing RF test and measurement investments, without exceeding increasingly constrained budgets.

RF operators have typically taken a “closed approach” to their RF measurement systems, building end-to-end solutions with equipment and components from a single vendor. However, these systems cannot always accommodate new requirements as they emerge. Attempting to integrate with equipment from other vendors introduces additional risk (to say nothing of technical complexity), because consistency of measurement is not guaranteed.

To mitigate this problem, A&D agencies are moving away from customized systems developed for military or government-specific initiatives and are insisting instead on commercial off-the-shelf (COTS) solutions from their vendors and integrators. Because commercially available technologies tend to evolve more quickly, they are proving to be more suitable for creating countermeasure systems that can adapt to an ever-evolving threat landscape—particularly when their opponents are using low-cost commercial technologies in their own EW efforts.

Ultimately, RF engineers are looking for RF test and monitoring solutions that can deliver functionality and performance, in a cost-effective manner. In a few instances, a purpose-built system may offer the advantage of a smaller overall footprint and simpler assembly, but more modular designs are easier to adjust. More importantly, they can be finely tuned to provide specific functionality tailored to specialized applications—without having to pay for features that are superfluous to the application at hand.

An open and interoperable approach to RF spectrum analysis provides the flexibility to build a solution around specialized applications and lowers the overall cost of increased performance. RF operators can continue to take advantage of emerging technologies and standards, while protecting their investment in existing equipment.

One specific example of such an approach helps RF operators meet the challenge of monitoring signals at higher frequencies: using a high-performing downconverter with signal analysis components that operate at lower frequency levels, to capture and analyze higher frequency signals without compromising on performance.

There is a need for a downconverter-tuner that can shift frequencies into the mmWave 5G frequency range, provides more flexibility with open application programming interface integration, provides greater coverage by delivering a compact for-factor for deployment in remote locations and monitoring capabilities of multiple locations, provides increased functionality for detecting complex waveforms in real-time and provides an upgrade without having to replace existing equipment.

References: [1] Market Research Future. (2019). Global RF Test Equipment Market Research Report: Information by Connectivity (Oscilloscope, Spectrum Analyzers, Signal Generators, Network Analyzers, and others), Form Factor (Bench-Top, Portable, and Modular), Frequency (Between 1 GHz to 6 GHz, More than 6 GHz and Less than 1 GHz), End User (IT & Telecommunications, Aerospace & Defense, Consumer Electronics, Automotive, Academic & Research Institutions, Industrial, Medical and others) and Region —Forecast till 2025. https://www.marketresearchfuture.com/reports/rf-test-equipment-market-5734

### BRIEF SUMMARY

It is the object of the present invention to provide a RF downconverter-tuner system.

In accordance with an aspect of the invention, there is provided a RF downconverter-tuner system to convert one or more input signals into a lower range of frequency bands, comprising one or more RF input ports for receiving the one or more input signals, one or more RF output ports for transmitting the output signal, a plurality of dual-mode switches coupled to two or more of the group consisting of the one or more RF input ports, the one or more RF output ports and one or more receive chains. The receive chain comprising one or more mixers for converting the one or more input signals into the lower range of frequency bands, a plurality of filters for eliminating one or more of unwanted signal artifacts, out-of-band signals and spurious products, a bypass mode for allowing for one or more of the input signals that are outside of a frequency range of the RF downconverter-tuner system to pass through to the one or more RF output ports, a back-end receiver coupled to the one or more RF output ports such that a selection of said input signals are processed by the back-end receiver, an oscillator implemented with a frequency synthesis circuit, a plurality of amplifier stages for increasing the strength of the input signal and for compensating for losses due to the one or more mixers and the plurality of filters, one or more signal detection circuits for detecting the level of the input signals at various stages in the receive chain and a plurality of controller ports for controlling the RF downconverter-tuner system.

In accordance with an embodiment of the invention, the output signal is a fixed frequency.

In accordance with an embodiment of the invention, the output signal is a center frequency.

In accordance with an embodiment of the invention, the center frequency is dependent on the input signal frequency.

In accordance with an embodiment of the invention, the center frequency is dependent on the frequency of the oscillator.

In accordance with an embodiment of the invention, the center frequency is dependent on the input signal frequency and the frequency of the oscillator.

In accordance with an embodiment of the invention, the output signal is dependent on other signals generated in the downconverter-tuner system.

In accordance with an embodiment of the invention, the output signal is dependent on the input frequency and other signals generated in the downconverter-tuner system.

In accordance with an embodiment of the invention, the frequency synthesis circuit is a phase-locked synthesizer.

In accordance with an embodiment of the invention, the controller ports are selected from the group consisting of one or more Ethernet ports, one or more USB ports and one or more Serial ports.

In accordance with an embodiment of the invention, the one or more RF output ports are an intermediate frequency (IF) output port.

In accordance with an embodiment of the invention, the oscillator is fixed.

In accordance with an embodiment of the invention, the oscillator is tunable.

In accordance with an embodiment of the invention, the oscillator is shared across multiple RF downconverter-tuners for synchronization.

In accordance with an embodiment of the invention, the plurality of filters are one or more filter banks.

In accordance with an embodiment of the invention, the filter bank comprises of one or more switchable analog pre-select filters.

In accordance with an embodiment of the invention, the filter bank includes overlapping frequency ranges within a processing range of the RF downconverter-tuner system.

In accordance with an embodiment of the invention, the filter bank includes a pass-through.

In accordance with an embodiment of the invention, the filter bank includes an unfiltered signal path.

In accordance with an embodiment of the invention, the one or more signal detection circuits are selected from the group consisting of analog detection circuits and digital detection circuits.

In accordance with an embodiment of the invention, the input signals have been downconverted.

In accordance with an embodiment of the invention, the input signals are outside of said frequency range.

In accordance with an embodiment of the invention, the oscillator is implemented with one or more Yttrium iron garnet spheres (YIG).

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates an aspect of the subject matter in accordance with one embodiment.

FIG. 2 illustrates an aspect of the subject matter in accordance with one embodiment.

FIG. 3 illustrates an aspect of the subject matter in accordance with one embodiment.

FIG. 4 illustrates an aspect of the subject matter in accordance with one embodiment.

FIG. 5 illustrates an aspect of the subject matter in accordance with one embodiment.

### DETAILED DESCRIPTION

The details of one or more embodiments of the subject matter of this specification are set forth in the accompanying drawings and the description below. Other features, aspects, and advantages of the subject matter will become apparent from the description, the drawings, and the claims.

Like reference numbers and designations in the various drawings indicate like elements.

As radio frequency (RF) signals push into higher and higher frequencies, RF engineers need test and measurement solutions that can capture those signals. If, for example, their existing test setup is designed to monitor Wi-Fi and 4G networks, the equipment may not be capable of capturing signals above 6 GHz. Instead of replacing their existing equipment with new components that support those higher frequencies, RF professionals can use a downconverter-tuner with their current test and measurement components to capture higher frequency signals—and preserve the capital expenditure (CapEx) investment they have made in their current RF instrumentation.

Downconverter-tuners represent a fairly simple concept—translating an incoming higher frequency RF signal to an intermediate frequency (IF) that's within the frequency range of the instrument being used to analyze it—but they're a powerful component for building high-performing and cost-effective RF signal monitoring solutions.

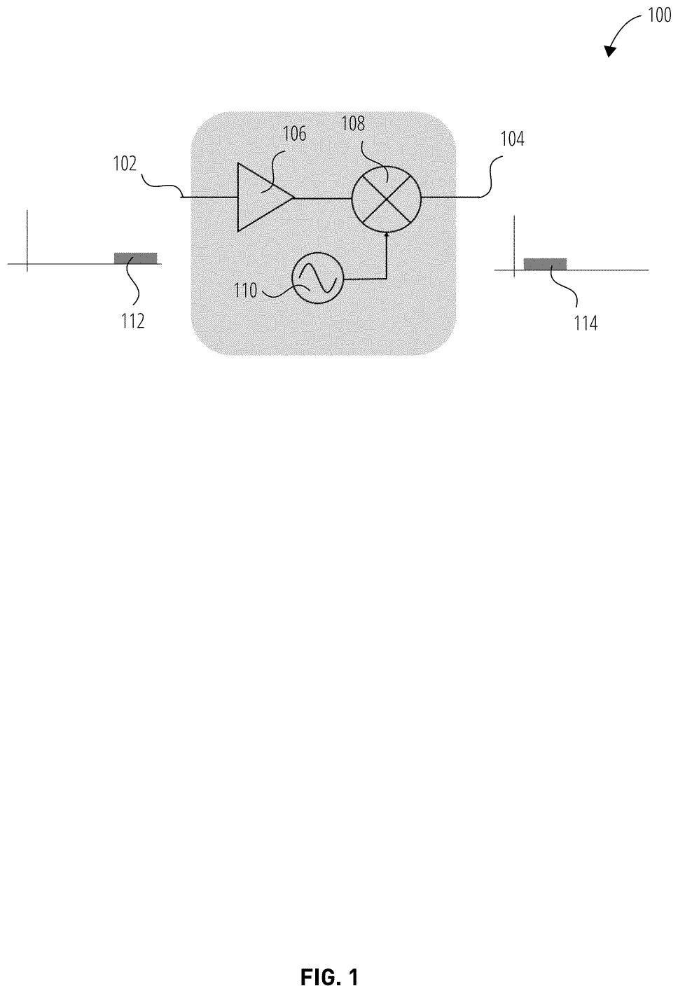

FIG. 1 depicts a simple downconverter architecture 100 as in one embodiment. Downconverters in general and quite simply, effectively multiply the existing RF range capabilities of the signal analyzers they connect to. They allow for measurements to be taken at much higher frequencies, be downconverted to an intermediate frequency (IF), and sent to the analyzer for post processing and analysis.

But not all downconverters are created equal: the myriad of downconverter options available on the market range in form factor (from integrated chips to 1-slot modules, to standalone components), capability (from upper limit frequencies of 6 GHz to 72 GHz), and price—and many are vendor-dependent, requiring complementary modules or chassis from the same manufacturer for operation.

A standard block downconverter takes a range of input signals frequencies and translates them down to a lower range of frequencies. In other words, the output frequency is not fixed but varies depending on the input frequency, which complicates the job of the receiver that it interfaces to. In addition, the block downconverter may not include a built-in local oscillator and sometimes requires the user to provide one externally—adding to cost, overall size, and complexity.

A simple downconverter can be built with only a few components. As shown in FIG. 1, a basic downconverter can be designed using a low noise analyzer (LNA 106), a mixer 108, and a fixed oscillator 110. In this example, an input frequency range 112 and the resulting output frequency 114 are displayed to illustrate the transformation from the RF input port 102 to the RF output port 104.

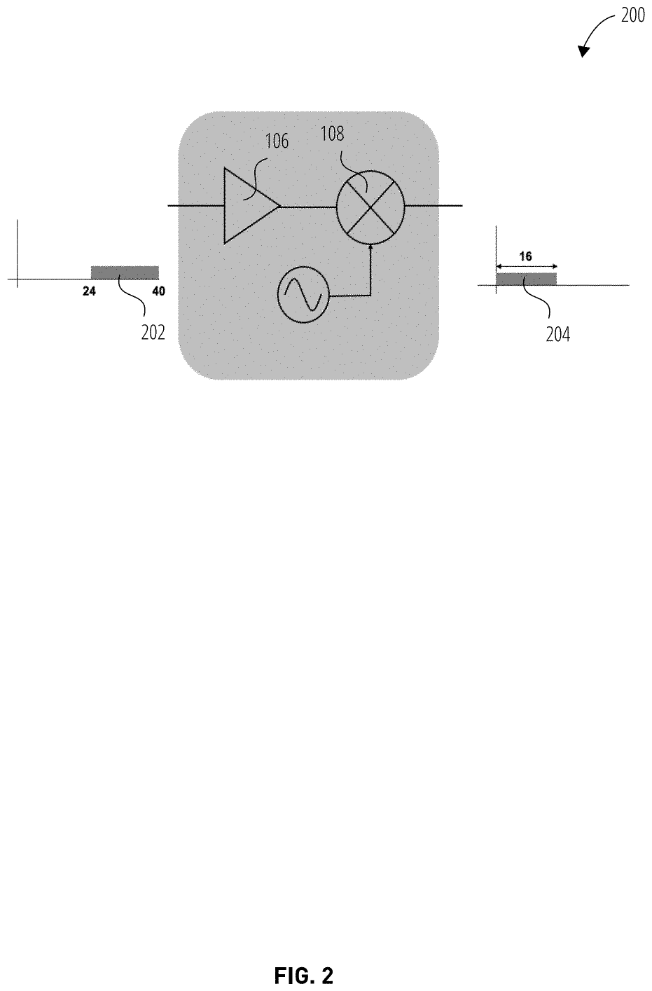

FIG. 2 depicts a block frequency translation 200 of a simple downconverter as in one embodiment. While this approach may be simple, it ultimately creates more challenges for users because it only enables block downconversion. The entire frequency range captured 202 by the downconverter is converted into a block of spectrum 204, which is then inputted into the analyzer operating over a lower frequency range. In this example, a 24-40 GHz RF downconverter design using this simple approach captures a 16 GHz block of spectrum. The 24 GHz band is converted to DC, while the 40 GHz band is converted to 16 GHz. A 6 GHz analyzer for instance would be unable to process the entire block of downconverted spectrum.

Even if the signal of interest falls within the range of the analyzer, a simple approach raises additional challenges. Since every LNA 106 and mixer 108 has gain characteristics that change with frequency, the downconverted signal would not be calibrated. This makes it impossible to see key signal properties, such as the amplitude of the signal at the RF input port.

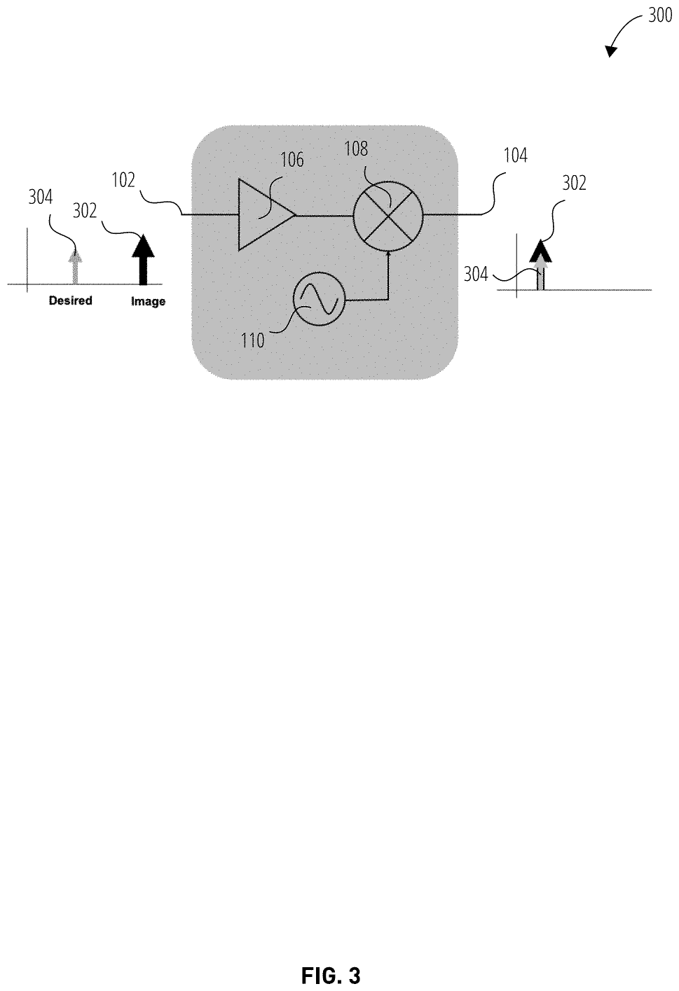

FIG. 3 depicts a desired signal masking in a block downconversion 300 of a simple downconverter as in one embodiment. Similarly, to the example in FIG. 2, due to the lack of any front-end filtering, there is the risk of creating spurious signals or increasing the noise floor to a level where the signal of interest is hidden. In this example, the RF input is represented by two potential frequencies, an image frequency 302 or a desired frequency 304.

Since the simple downconverter lacks front-end filtering, there's no way to block out or differentiate between the image frequency 302 and the desired frequency 304. This problem travels downstream, resulting in a tuned output frequency which is indistinguishable between an input image frequency 302 or desired frequency 304.

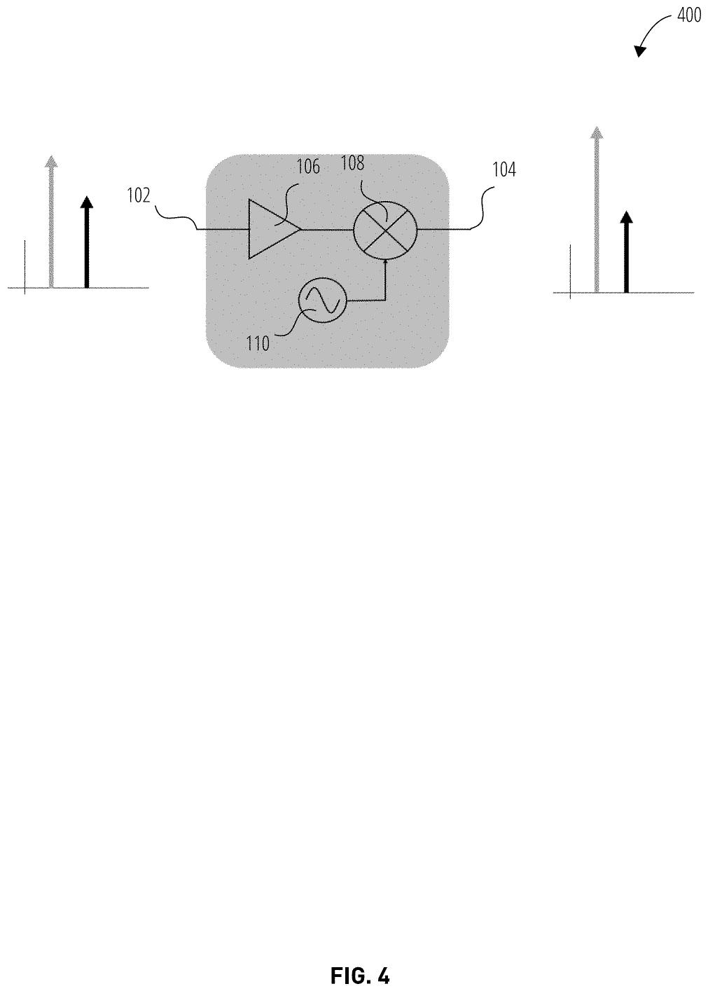

FIG. 4 depicts a lack of calibration information 400 of a simple downconverter as in one embodiment. This approach typically involves using off-the-shelf components that require a large form factor and complex integration such as a complex RF integration with tunable oscillators, complex filter banks, increasing costs and time. Furthermore, extensive RF expertise is required to successfully integrate equipment, while the increased size, weight, and power requirements means that the combined solution is not suitable for use in the field.

Rather than taking this simple approach, it is far better for RF professionals to integrate with a more sophisticated RF downconverter-tuner that takes on more complexity in the unit itself. With more capabilities and better performance, the user gets a simple, easy-to-use, and economical solution.

Unlike a typical downconverter that only downconverts a block of spectrum, the downconverter-tuner, presented hereafter, operates in two modes. It either:
1. Always converts the tuned or desired frequency to a single fixed IF output or
2. Block downconverts a larger filtered or unfiltered block of spectrum whereby there is no concept of tuning—rather a simple conversion down to a final IF output that is the sum or difference of signals one of which is the input frequency.

where signal at the IF output is processed by a back-end receiver such as that in a software defined radio, a conventional analog or digital radio system or spectrum analyzer.

The RF downconverter-tuner system is employed to convert one or more input signals into a lower range of frequency bands and comprises one or more RF input ports for receiving the one or more input signals, one or more RF output ports for transmitting the output signal and a plurality of dual-mode switches coupled to two or more of the group consisting of the one or more RF input ports, the one or more RF output ports and one or more receive chains.

In some embodiments, the output signal is a fixed frequency such as an IF and the one or more RF output ports are an IF output port. In other embodiments, the output signal is a center frequency. In some embodiments, the center frequency may be dependent on the input signal frequency. In other embodiments, the center frequency may be dependent on the frequency of the oscillator. In other embodiments, the center frequency may be dependent on the input signal frequency and the frequency of the oscillator. In some embodiments, the output signal is dependent on other signals generated in the downconverter-tuner system. In other embodiments, the output signal is dependent on the input frequency and other signals generated in the downconverter-tuner system.

The receive chain comprises one or more mixers for converting the one or more input signals into the lower range of frequency bands and a plurality of filters for eliminating one or more of unwanted signal artifacts, band signals and spurious products. In some embodiments, the plurality of filters are one or more filter banks. In some embodiments, the filter bank comprises of one or more switchable analog pre-select filters. In some embodiments, the filter bank includes overlapping frequency ranges within a processing range of the RF downconverter-tuner system. In some embodiments, the filter bank includes a pass-through. In some embodiments, the filter bank includes is an unfiltered signal path.

The receive chain further comprises a bypass mode for allowing for one or more of the input signals that are outside of a frequency range of the RF downconverter-tuner system to pass through to the one or more RF output ports, a back-end receiver coupled to the one or more RF output port such that that a selection of the input signals are processed by the back-end receiver and an oscillator implemented with a frequency synthesis circuit. In some embodiments, the input signals that have been downconverted. In some embodiments, the input signals are outside of said frequency range. In some embodiments, the frequency synthesis circuit is a phase-locked loop synthesizer. In some embodiments, the oscillator is fixed. In other embodiments, the oscillator is tunable. In some embodiments, the oscillator is shared across multiple RF downconverter-tuners for synchronization.

The receive chain further comprises a plurality of amplifier stages for increasing the strength of the input signal and for compensating for losses due to the one or more mixers and the plurality of filters, one or more signal detection circuits for detecting the level of the input signals at various stages in the receive chain and a plurality of controller ports for controlling the RF downconverter-tuner system. In some embodiments, the controller ports are selected from the group consisting of one or more Ethernet ports, one or more USB ports and one or more Serial ports. In some embodiments, the one or more signal detection circuits are selected from the group consisting of analog detection circuits and digital detection circuits.

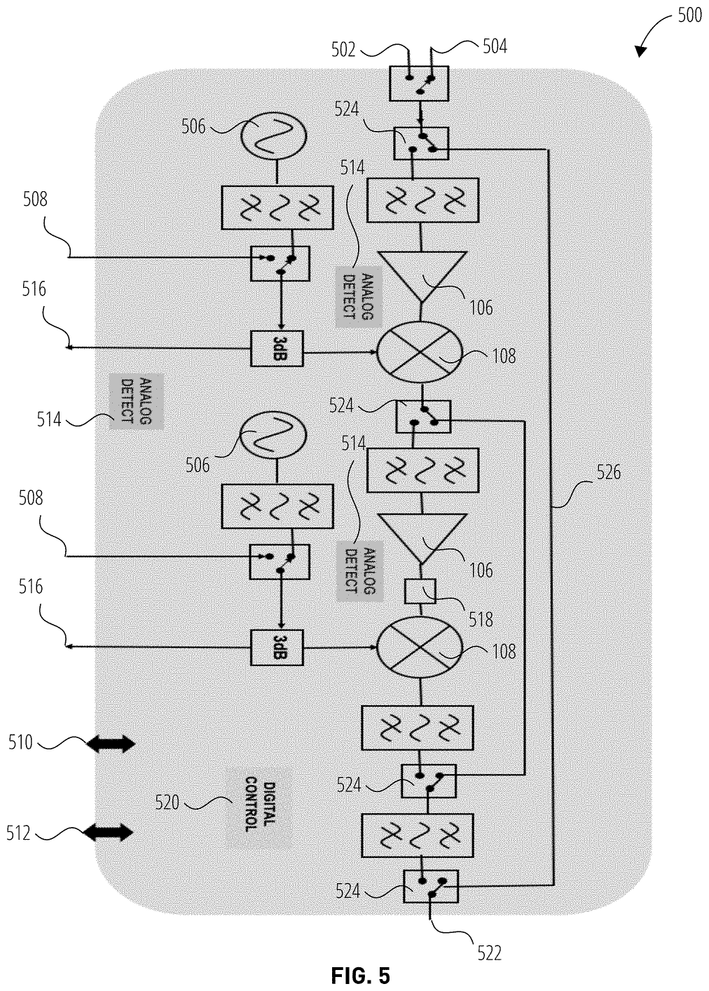

FIG. 5 depicts a block diagram 500 of a RF downconverter-tuner system as in one embodiment. Dual identical antenna inputs enable the user to connect two antennas covering different frequency ranges which may overlap for contiguous frequency coverage. A pre-select filter bank, which also includes an unfiltered bypass mode 526, is used to filter signals that would otherwise result in spurious responses at the IF output 522. The dual-mode switches 524 allow for the RF input 1 502 and RF input 2 504 to either continue to the receive chain or to be transmitted as IF output 522. Multiple gain blocks by way of low noise amplifiers are included in the receiver chain to reduce noise figure, thereby enhancing sensitivity. The receive chain includes multiple banks of analog filters to reject unwanted signals such as local oscillator feedthrough for instance.

The receive chain includes one or more mixer stages. At least one mixer stage is required to downconvert the signal, while additional mixing stages may be utilized or bypassed depending on the requirements for the final IF output 522. In a first mode of operation, the RF downconverter-tuner includes built-in phase-locked loop synthesizers (PLL synthesizers 506) or Yttrium Iron Garnet oscillators (YIG oscillators) acting as local oscillators (LO) that are automatically tuned across their frequency range to convert the signal from the extension PLL input 508, to the PLL output 516 and the desired single final IF output 522. The frequency to which each LO tunes is pre-determined by design and optimized for minimization of spurious output signals.

In a second mode of operation, these synthesizers operate at a fixed frequency to downconvert all received signals to final IF output 522 frequencies that depend on mathematical difference or sum of the input frequency and the oscillator frequency. The device therefore operates in two modes.

Built-in LO, displayed as PLL synthesizers 506, are used by the RF downconverter-tuner and shared by coupling it to an RF output port 104. This signal in turn can be input to another similar RF downconverter-tuner and enables phase coherence and synchronization across multiple units.

Adjustable attenuator blocks (ATT 518) in the RF downconverter-tuner enable built-in calibration. Put simply, the attenuator is used to adjust the signal level such that the output signal is equal in value to the input. The adjustment value at each frequency is pre-determined and programmed into the downconverter-tuner. Each downconverter-tuner is individually calibrated. Calibration enables accurate signal measurement and also easy integration with calibrated equipment. Compared to the simple approach, amplitude and other properties at the RF input 1 502 and RF input 2 504 are known based on the signal out of the downconverter-tuner, allowing for more accurate and in-depth analysis.

This embodiment also features an ethernet control and feedback port 510, digital control 520 and 10 MHz In/Out port 512.

The receive chain in this RF downconverter-tuner example includes analog detection circuits 514 that detect the level of analog signals at various stages in the receive chain starting at the input. This information is used to detect a signal overload condition and accordingly the digital control circuit acts to increase the amount of attenuation and reduce the signal level.

The RF downconverter-tuner is controlled via a PC, across a network or through a spectrum analyzer, the RF downconverter-tuner uses Standard Commands for Programmable Instruments (SCPI) controls over Ethernet. A rich suite of application programming interfaces (APIs) and programming environments, including but not limited to C, C++, and Python, enables users to run their existing applications with minimal integration requirements.

Applications for the downconverter-tuner include as data recording, spectrum monitoring, interference hunting, network performance monitoring, signal analysis, test and measurement, RF drive-test and RF research & development.

The foregoing descriptions of specific embodiments of the present invention have been presented for purposes of illustration and description. They are not intended to be exhaustive or to limit the invention and method of use to the precise forms disclosed. Obviously, many modifications and variations are possible in light of the above teaching. The embodiments described were chosen and described in order to best explain the principles of the invention and its practical application, and to thereby enable others skilled in the art to best utilize the invention and various embodiments with various modifications as are suited to the particular use contemplated. It is understood that various omissions or substitutions of equivalents are contemplated as circumstance may suggest or render expedient but is intended to cover the application or implementation without departing from the spirit or scope of the claims of the present invention.

What is claimed is:

1. A RF downconverter-tuner system to convert one or more input signals into a lower range of frequency bands, comprising:
one or more RF input ports for receiving said one or more input signals;
one or more RF output ports for transmitting said output signal;
a plurality of dual-mode switches coupled to two or more of the group consisting of said one or more RF input ports, said one or more RF output ports and one or more receive chains;
said receive chain comprising:
one or more mixers for converting said one or more input signals into said lower range of frequency bands;
a plurality of filters for eliminating one or more of unwanted signal artifacts, band signals and spurious products;
a bypass mode for allowing for one or more of said input signals that are outside of a frequency range of said RF downconverter-tuner system to pass through to said one or more RF output ports,
a back-end receiver coupled to said one or more RF output ports such that a selection of said input signals are processed by said back-end receiver;
an oscillator implemented with a frequency synthesis circuit;
a plurality of amplifier stages for increasing the strength of said input signal and for compensating for losses due to said one or more mixers and said plurality of filters;
one or more signal detection circuits for detecting the level of said input signals at various stages in said receive chain; and
a plurality of controller ports for controlling said RF downconverter-tuner system.

2. The RF downconverter-tuner system of claim 1, wherein said output signal is a fixed frequency.

3. The RF downconverter-tuner system of claim 1, wherein said output signal is a center frequency.

4. The RF downconverter-tuner system of claim 3, wherein said center frequency is dependent on the input signal frequency.

5. The RF downconverter-tuner system of claim 3, wherein said center frequency is dependent on the frequency of said oscillator.

6. The RF downconverter-tuner system of claim 3, wherein said center frequency is dependent on the input signal frequency and the frequency of said oscillator.

7. The RF downconverter-tuner system of claim 1, wherein said output signal is dependent on other signals generated in the downconverter-tuner system.

8. The RF downconverter-tuner system of claim 1, wherein said output signal is dependent on the input frequency and other signals generated in the downconverter-tuner system.

9. The RF downconverter-tuner system of claim 1, wherein said frequency synthesis circuit is a phase-locked synthesizer.

10. The RF downconverter-tuner system of claim 1, wherein said controller ports are selected from the group consisting of one or more Ethernet ports, one or more USB ports and one or more Serial ports.

11. The RF downconverter-tuner system of claim 1, wherein said one or more RF output ports are an intermediate frequency (IF) output port.

12. The RF downconverter-tuner system of claim 1, wherein said oscillator is fixed.

13. The RF downconverter-tuner system of claim 1, wherein said oscillator is tunable.

14. The RF downconverter-tuner system of claim 1, wherein said oscillator is shared across multiple RF downconverter-tuners for synchronization.

15. The RF downconverter-tuner system of claim 1, wherein said plurality of filters are one or more filter banks.

16. The RF downconverter-tuner system of claim 15, wherein said filter bank comprises of one or more switchable analog pre-select filters.

17. The RF downconverter-tuner system of claim 15, wherein said filter bank includes overlapping frequency ranges within a processing range of said RF downconverter-tuner system.

18. The RF downconverter-tuner system of claim 15, wherein said filter bank includes an unfiltered signal path.

19. The RF downconverter-tuner system of claim 16, wherein said filter bank includes a pass-through.

20. The RF downconverter-tuner system of claim 1, wherein said one or more signal detection circuits are selected from the group consisting of analog detection circuits and digital detection circuits.

21. The RF downconverter-tuner system of claim 1, wherein said input signals have been downconverted.

22. The RF downconverter-tuner system of claim 1, wherein said input signals are outside of said frequency range.

23. The RF downconverter-tuner system of claim 1, wherein said oscillator is implemented with one or more Yttrium iron garnet spheres (YIG).
